(19) United States
(12) Patent Application Publication
(10) Pub. No.: US 2023/0044283 A1
(43) Pub. Date: Feb. 9, 2023

(54) METHOD OF MANUFACTURING CHIP

(71) Applicant: DISCO CORPORATION, Tokyo (JP)

(72) Inventor: Fumiya KAWANO, Tokyo (JP)

(21) Appl. No.: 17/812,579

(22) Filed: Jul. 14, 2022

(30) Foreign Application Priority Data
Aug. 4, 2021 (JP) 2021-128544

(51) Int. Cl. B23K 26/382; B23K 26/073; H01L 21/82

(52) U.S. Cl. CPC B23K 26/382; B23K 26/073; H01L 21/8213; B23K 2101/40

(57) ABSTRACT

A method of manufacturing an optionally shaped chip from a substrate having a crystalline structure includes establishing a projected dicing line on the substrate representing a contour of a chip to be fabricated from the substrate, and establishing a straight division assisting line contacting the contour of the chip for assisting in dividing the substrate. A division initiating point is formed after the projected dicing line is established and a laser beam is applied along the contour of the chip and the division assisting line while positioning a focused spot of the laser beam in the substrate at a predetermined position spaced from an upper surface of the substrate, thereby forming division initiating points in the substrate. The substrate is divided by applying external forces to the substrate in which the division initiating points have been formed, to divide the substrate along the division initiating points.

### BACKGROUND OF THE INVENTION

### Field of the Invention

The present invention relates to a method of manufacturing a chip from a substrate having a crystalline structure.

### Description of the Related Art

For manufacturing chips of desired shapes from a plate-shaped workpiece such as a glass substrate, there have been used in the art a laser processing apparatus capable of applying a laser beam to the workpiece along the profiles of chips to be fabricated. Such a laser processing apparatus includes a laser processing apparatus for applying a laser beam having a wavelength transmittable through a plate-shaped workpiece to the plate-shaped workpiece while positioning the focused spot of the laser beam within the plate-shaped workpiece, thereby forming modified layers in the plate-shaped workpiece (see Japanese Patent No. 3408805) and a laser processing apparatus for applying a laser beam having a wavelength transmittable through a plate-shaped workpiece to the plate-shaped workpiece while positioning the focused spot of the laser beam at required positions, thereby forming shield tunnels made up of pores and an amorphous material surrounding the pores (see Japanese Patent Laid-open No. 2014-221483).

The modified layers and the shield tunnels described above function as division initiating points along which the plate-shaped workpiece can be divided into a plurality of individual chips by external forces applied to the plate-shaped workpiece. In some cases, a plate-shaped workpiece is divided into a plurality of individual circular chips along annular arrays of division initiating points formed in the workpiece. However, in the plate-shaped workpiece from which circular chips are to be fabricated, regions inside and outside of the annular arrays of division initiating points are kept in intimate contact with each other along curved lines in the workpiece. It is difficult to divide those regions efficiently and reliably from each other as the dividing process needs to be performed manually and hence inefficiently by a skilled worker.

The inventors of the present invention have developed a dividing tool capable of reliably and efficiently dividing a plate-shaped workpiece along annular arrays of division initiating points formed therein (see Japanese Patent Laid-open No. 2017-202589). The dividing tool is effective to reliably divide substrates of glass or the like that are not crystalline into circular chips.

### SUMMARY OF THE INVENTION

However, crystalline substrates made of silicon carbide (SiC) or the like are highly likely to crack along their crystal orientation when efforts are made to divide them, even when the dividing tool referred to above is used. Consequently, a new challenge has arisen in the art that it is difficult to cut optionally shaped chips from crystalline substrates.

It is therefore an object of the present invention to provide a method of manufacturing an optionally shaped chip reliably from a crystalline substrate.

In accordance with an aspect of the present invention, there is provided a method of manufacturing an optionally shaped chip from a crystalline substrate, including a projected dicing line establishing step of establishing on the substrate a contour of a chip to be fabricated from the substrate and a straight division assisting line contacting the contour of the chip for assisting in dividing the substrate, a division initiating point forming step of, after the projected dicing line establishing step, applying a laser beam having a wavelength transmittable through the substrate to the substrate along the contour of the chip and the division assisting line while positioning a focused spot of the laser beam in the substrate at a predetermined position spaced from an upper surface of the substrate, thereby forming division initiating points in the substrate, and a dividing step of applying external forces to the substrate in which the division initiating points have been formed, to divide the substrate along the division initiating points, in which the division assisting line extends across all sides of unit lattices through which the division assisting line extends, of all unit lattices of the crystalline structure, and is tangential to the contour of the chip to be fabricated from the substrate, on the upper surface of the substrate.

Preferably, the division assisting line extends perpendicularly across those sides extending in one direction of the unit lattices that make up the crystalline structure of the substrate, on the upper surface of the substrate. Preferably, the substrate is a substrate made of SiC.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a flowchart of the sequence of a method of manufacturing a chip according to an embodiment of the present invention;

FIG. 2 is a fragmentary schematic plan view of a substrate that has undergone a projected dicing line establishing step of the method illustrated in FIG. 1;

FIG. 3 is a fragmentary schematic perspective view of a state in a division initiating point forming step of the method illustrated in FIG. 1;

FIG. 4 is a fragmentary schematic perspective view of the substrate that has undergone the division initiating point forming step of the method illustrated in FIG. 1;

FIG. 5 is an enlarged fragmentary cross-sectional view of a portion of the substrate illustrated in FIG. 4;

FIG. 6 is an enlarged fragmentary cross-sectional view of a portion of the substrate illustrated in FIG. 5;

FIG. 7 is a perspective view of a shield tunnel formed in the substrate illustrated in FIG. 4;

FIG. 8 is a schematic side elevational view of a state in a dividing step of the method illustrated in FIG. 1;

FIG. 9 is a schematic side elevational view of a state after the dividing step of the method illustrated in FIG. 1;

FIG. 10 is a schematic perspective view of the substrate in a state in the dividing step of the method illustrated in FIG. 1;

FIG. 11 is a fragmentary schematic plan view of a substrate divided along division assisting lines according to a first comparative example; and

FIG. 12 is a fragmentary schematic plan view of a substrate divided along division assisting lines according to a second comparative example.

### DETAILED DESCRIPTION OF THE PREFERRED EMBODIMENT

A preferred embodiment of the present invention will be described in detail hereinbelow with reference to the accompanying drawings. The present invention is not limited to the details of the embodiment described below. The components described below cover those which could easily be anticipated by those skilled in the art and those which are essentially identical to those described above. Further, the arrangements described below can be combined in appropriate manners. Various omissions, replacements, or changes of the arrangements may be made without departing from the scope of the present invention. In the description to be described below, those components that are identical to each other are denoted by identical reference characters.

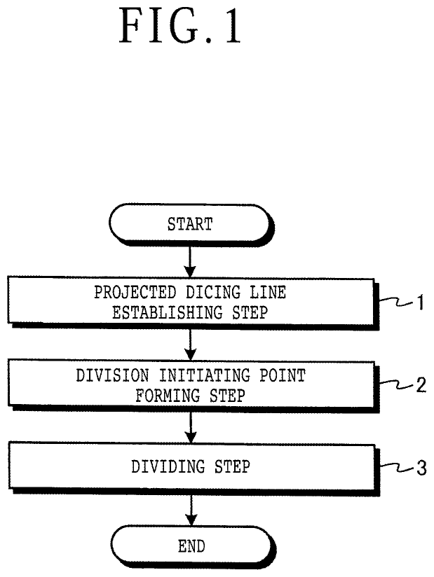

A method of manufacturing a chip according to the present embodiment will be described below with reference to the drawings. FIG. 1 is a flowchart of the sequence of the method of manufacturing a chip according to the present embodiment. As illustrated in FIG. 1, the method of manufacturing a chip according to the present embodiment includes a projected dicing line establishing step 1, a division initiating point forming step 2, and a dividing step 3. These steps of the method will successively be described below.

(Projected Dicing Line Establishing Step 1)

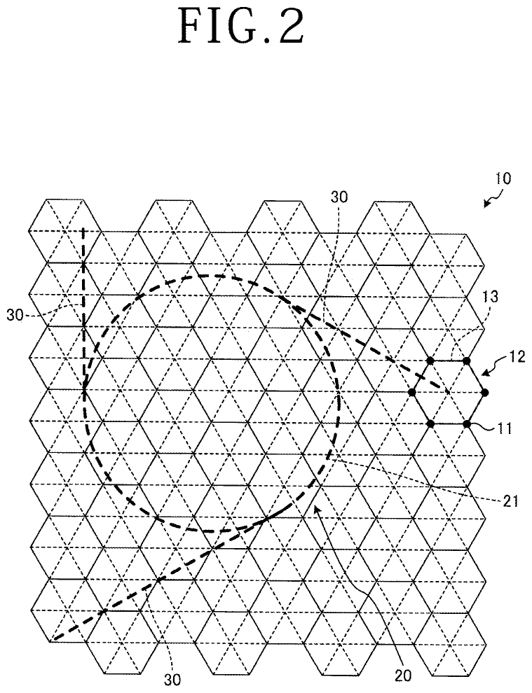

FIG. 2 schematically illustrates in plan a substrate 10 that has undergone the projected dicing line establishing step 1 of the method illustrated in FIG. 1. The projected dicing line establishing step 1 is a step of establishing on the substrate 10 a contour 21 of a chip 20 to be fabricated from the substrate 10 and straight division assisting lines 30 contacting the contour 21 for assisting in dividing the substrate 10.

The substrate 10 is a plate-shaped workpiece made of SiC or the like. The substrate 10 has a crystalline structure. As illustrated in FIG. 2, the substrate 10 according to the present embodiment has unit lattices 12 each including six interconnected lattice points 11 and having a hexagonal shape as viewed in plan. The substrate 10 has an orientation flat or notch representing the crystal orientation thereof.

In the projected dicing line establishing step 1, first, the contour 21 of the chip 20 to be fabricated from the substrate 10 is established on an upper surface of the substrate 10. According to the present embodiment, the contour 21 of the chip 20 represents a circular shape. Although the contour 21 of the chip 20 represents a circular shape according to the present embodiment, it is not limited to a circular shape, and may be of any desired shape, i.e., optional shape, according to the present invention.

In the projected dicing line establishing step 1, then, the division assisting lines 30 are established on the upper surface of the substrate 10. The division assisting lines 30 are straight lines for assisting in dividing the substrate 10 into the chip 20. The division assisting lines 30 are tangential to the contour 21 of the chip 20 to be fabricated from the substrate 10. The division assisting lines 30 are established in such a manner as not to lie parallel to any of lines interconnecting the lattice points 11 of the unit lattices 12, i.e., any of sides 13 of the unit lattices 12. Stated otherwise, the division assisting lines 30 are established in such a manner as to extend across all the sides 13 of the unit lattices 12 through which the division assisting lines 30 extend or extensions of those sides 13. According to the present embodiment, the division assisting lines 30 are established in such a manner as to extend perpendicularly across those sides 13 extending in one direction of the unit lattices 12 that make up the crystalline structure of the substrate 10.

(Division Initiating Point Forming Step 2)

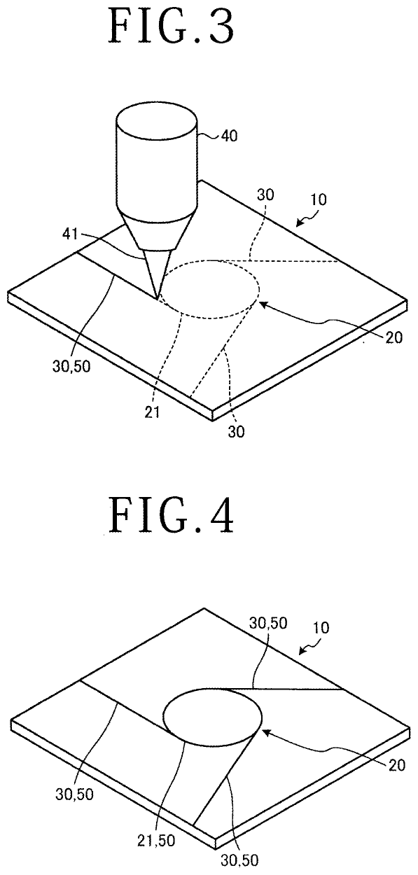

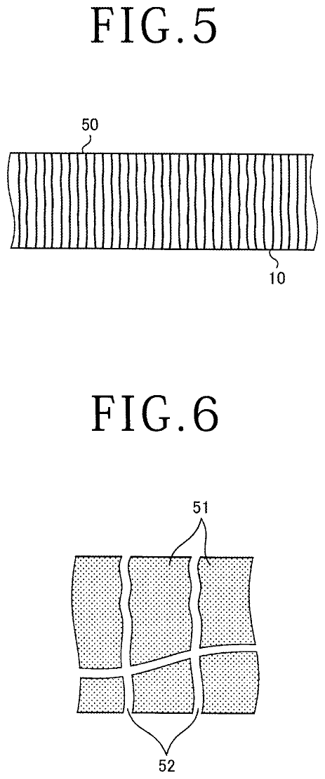

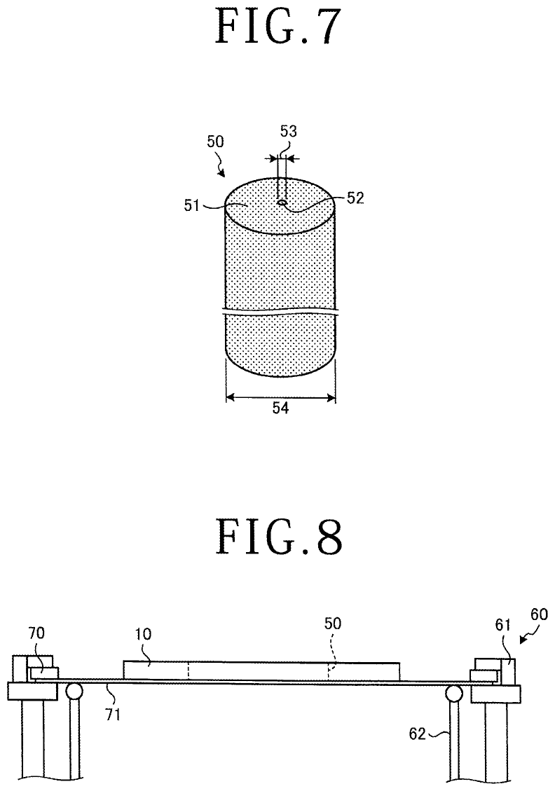

FIG. 3 schematically illustrates in perspective a state in the division initiating point forming step 2 of the method illustrated in FIG. 1. FIG. 4 illustrates in perspective the substrate 10 after the division initiating point forming step 2 of the method illustrated in FIG. 1. FIG. 5 illustrates in enlarged fragmentary cross section a portion of the substrate 10 illustrated in FIG. 4. FIG. 6 illustrates in enlarged fragmentary cross section a portion of the substrate 10 illustrated in FIG. 5. FIG. 7 illustrates in perspective a shield tunnel 50 formed in the substrate 10 illustrated in FIG. 4.

The division initiating point forming step 2 is a step of forming division initiating points in the substrate 10 for dividing the substrate 10 into the chip 20. According to the present embodiment, the division initiating points are shield tunnels 50. In the division initiating point forming step 2 according to the present embodiment, the shield tunnels 50 are formed in the substrate 10 by a laser processing apparatus. The laser processing apparatus includes an unillustrated support table for supporting the substrate 10 thereon, a laser beam applying unit 40, and an unillustrated moving unit for moving the support table and the laser beam applying unit 40 relative to each other.

The laser beam applying unit 40 applies a laser beam 41 to the substrate 10 supported on the support table of the laser processing apparatus. The laser beam 41 has a wavelength transmittable through the substrate 10.

In the division initiating point forming step 2, the support table that supports the substrate 10 and the laser beam applying unit 40 are moved relative to each other to position the focused spot of the laser beam 41 in the substrate 10 at a predetermined position spaced from the upper surface of the substrate 10. Then, the laser beam 41 is applied to the inside of the substrate 10 while the substrate 10 and the laser beam applying unit 40 are being moved relative to each other, to apply the laser beam 41 along the contour 21 of the chip 20 and the division assisting lines 30.

When the laser beam 41 is thus applied to the substrate 10, pores 52 and amorphous modified regions 51 surrounding the pores 52 are grown in the substrate 10 from around the focused spot of the laser beam 41 positioned in the substrate 10 toward the upper surface of the substrate 10 along the contour 21 of the chip 20 and the division assisting lines 30, forming shield tunnels 50 spaced at predetermined intervals in the substrate 10, as illustrated in FIGS. 5 and 6. As illustrated in FIG. 7, each of the pores 52 has an inside diameter 53 of approximately 1 μm, each of the modified regions 51 has an outside diameter 54 of approximately 5 μm, and adjacent two of the modified regions 51 are spaced from each other at an interval of approximately 10 μm.

(Dividing Step 3)

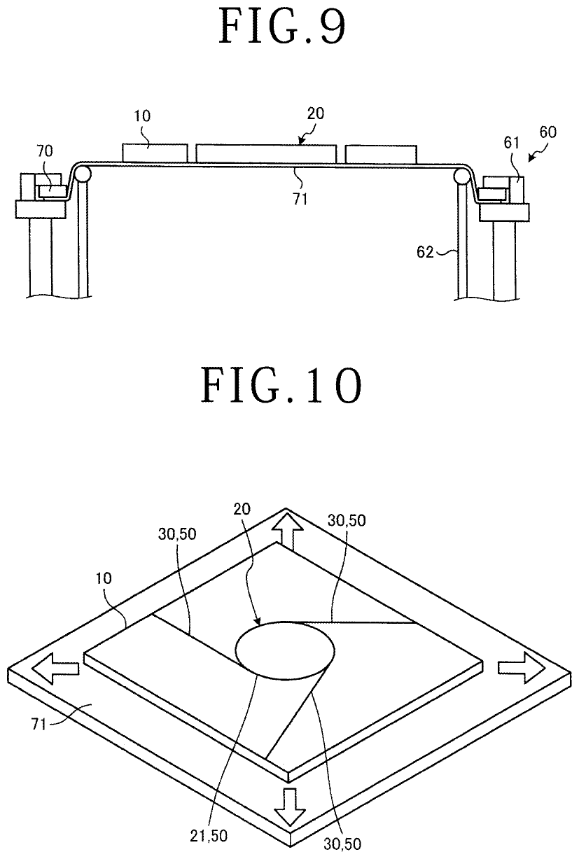

FIG. 8 schematically illustrates in side elevation a state in the dividing step 3 of the method illustrated in FIG. 1. FIG. 9 schematically illustrates in side elevation a state after dividing step 3 of the method illustrated in FIG. 1. FIG. 10 schematically illustrates in perspective the substrate 10 in a state in the dividing step 3 of the method illustrated in FIG. 1.

The dividing step 3 is a step of dividing the substrate 10 into the chip 20 along the division initiating points, i.e., the shield tunnels 50, formed in the substrate 10. In the dividing step 3 according to the present embodiment, external forces are applied to the substrate 10 by use of an expanding apparatus 60 to divide the substrate 10. The expanding apparatus 60 includes a plurality of clamps 61 and a plurality of pushers 62.

In the dividing step 3, an expandable tape 71 is affixed to an annular frame 70 and the substrate 10 that is surrounded by the annular frame 70, securing the substrate 10 in the opening of the annular frame 70. Then, an outer circumferential edge portion of the annular frame 70 is clamped in position by the clamps 61. At this time, the pushers 62 have respective upper tip ends held in abutment against a region of the expandable tape 71 that lies between an inner circumferential edge portion of the annular frame 70 and an outer circumferential edge portion of the substrate 10. Rollers should preferably be mounted on the respective upper tip ends of the pushers 62.

Then, in the dividing step 3, the pushers 62 are lifted relatively to the clamps 61. Since the expandable tape 71 has its outer circumferential edge portion fixed in position by the clamps 61 with the annular frame 70 interposed therebetween, a region of the expandable tape 71 that lies between the inner circumferential edge portion of the annular frame 70 and the contour 21 of the chip 20 included in the substrate 10 is radially outwardly expanded in its plane. As radially outward tensile forces are applied to the expandable tape 71 to expand the expandable tape 71, the chip 20 in the substrate 10 and portions of the substrate 10 that lie outside of the chip 20 and are demarcated by the division assisting lines 30 are divided from each other along the contour 21 and the division assisting lines 30 that act as boundaries.

### First Comparative Example

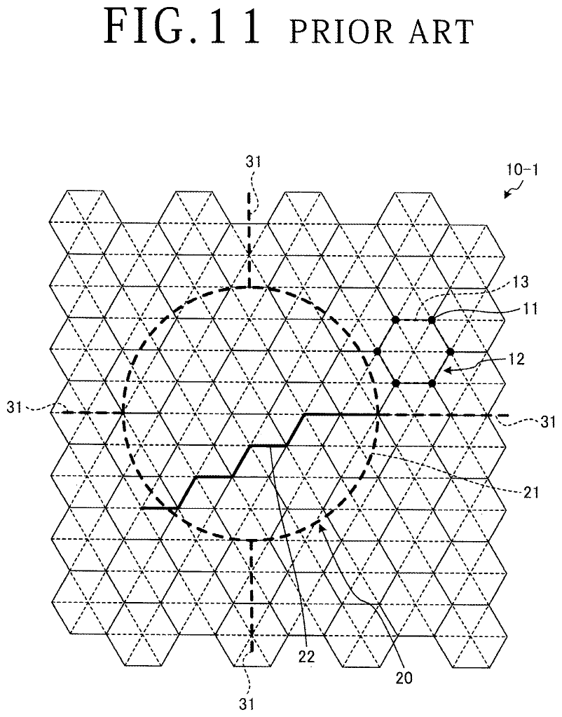

FIG. 11 schematically illustrates in plan a substrate 10-1 divided along division assisting lines 31 according to a first comparative example. The division assisting lines 31 according to the first comparative example are lines contacting the contour 21 of the chip 20 to be fabricated from the substrate 10-1 and extending normal to the contour 21 and radially outwardly from the chip 20, on an upper surface of the substrate 10-1.

According to the first comparative example, in the projected dicing line establishing step 1, the contour 21 of the chip 20 to be fabricated from the substrate 10-1 and the division assisting lines 31 are established on the upper surface of the substrate 10-1. Thereafter, the division initiating point forming step 2 and the dividing step 3 are successively carried out on the substrate 10-1 in the same manner as that in the embodiment. According to the first comparative example, as illustrated in FIG. 11, the divided chip 20 has a crack 22 extending from the joint between one of the division assisting lines 31 and the contour 21 of the chip 20 into the chip 20 and developed away from the division assisting line 31 through the chip 20 across the contour 21.

### Second Comparative Example

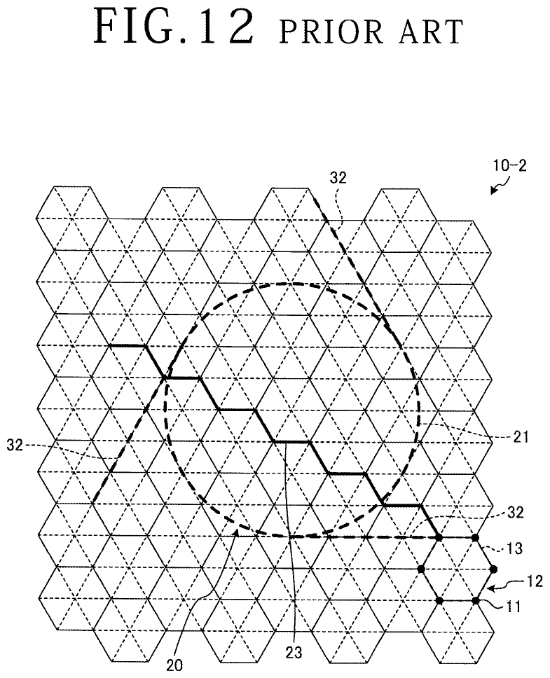

FIG. 12 schematically illustrates in plan a substrate 10-2 divided along division assisting lines 32 according to a second comparative example. The division assisting lines 32 according to the second comparative example are lines tangential to the contour 21 of the chip 20 to be fabricated from the substrate 10-2 and parallel to those sides 13 extending in certain directions of the unit lattices 12 that make up the crystalline structure of the substrate 10-2, on an upper surface of the substrate 10-2.

According to the second comparative example, in the projected dicing line establishing step 1, the contour 21 of the chip 20 to be fabricated from the substrate 10-2 and the division assisting lines 32 are established on the upper surface of the substrate 10-2. Thereafter, the division initiating point forming step 2 and the dividing step 3 are successively carried out on the substrate 10-2 in the same manner as that in the embodiment. According to the second comparative example, as illustrated in FIG. 12, the divided chip 20 has a crack 23 extending across the division assisting lines 32 and developed through the chip 20.

With the method of manufacturing a chip according to the present embodiment described above, the division assisting lines 30 to be formed on the substrate 10 outside of the contour 21 of the chip 20 to be fabricated from the substrate 10 are established in consideration of the crystal orientation of the substrate 10 in order to obtain the optionally shaped chip 20 from the substrate 10.

In the projected dicing line establishing step 1, for example, each of the division assisting lines 30 is established perpendicularly to a diagonal line of the hexagonal shape of a unit lattice 12, i.e., a line interconnecting remotest lattice points 11 of the unit lattice 12, according to the embodiment. However, if the substrate 10 is of a hexagonal crystal structure, then a division assisting line 30 may be established at an angle ranging from 60° to 120° with respect to a diagonal line of the hexagonal shape. If the substrate 10 is of a tetragonal crystal structure, then a division assisting line 30 may be established at an angle ranging from 0° to 180° with respect to a diagonal line of the quadrangular shape.

By thus establishing a division assisting line at an angle ideal for division with respect to the crystal orientation of the substrate 10, the probability that cracks 22 and 23 will be created in the substrate 10 at the time the substrate 10 is divided are significantly reduced, making it possible to obtain an optionally shaped chip 20 reliably from the substrate 10.

The present invention is not limited to the above embodiment, and various changes and modifications may be made in the embodiment without departing from the scope of the invention.

For example, an etching process may be performed on the substrate 10 after the division initiating point forming step 2 but before the dividing step 3. In the dividing step 3, the substrate 10 is divided by being expanded by the expanding apparatus 60 according to the above embodiment. However, the substrate 10 may be divided using the dividing tool disclosed in Japanese Patent Laid-open No. 2017-202589.

According to the above embodiment, one chip 20 is formed in one substrate 10. According to the present invention, however, a plurality of chips 20 may be formed in one substrate 10. In the latter case, it is preferable to establish on one substrate 10 a plurality of sets each having a contour 21 of a chip 20 and a plurality of division assisting lines 30 combined therewith, and to establish additional division assisting lines demarcating a plurality of areas on the substrate 10 that are assigned respectively to the sets. The additional division assisting lines thus established are effective to prevent cracks from being developed in the chips 20 due to stresses from adjacent ones of the chips 20 and the division assisting lines 30.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of manufacturing an optionally shaped chip from a substrate having a crystalline structure, comprising:
a projected dicing line establishing step of establishing on the substrate a contour of a chip to be fabricated from the substrate and a straight division assisting line contacting the contour of the chip for assisting in dividing the substrate;
a division initiating point forming step of, after the projected dicing line establishing step, applying a laser beam having a wavelength transmittable through the substrate to the substrate along the contour of the chip and the division assisting line while positioning a focused spot of the laser beam in the substrate at a predetermined position spaced from an upper surface of the substrate, thereby forming division initiating points in the substrate; and
a dividing step of applying external forces to the substrate in which the division initiating points have been formed, to divide the substrate along the division initiating points,
wherein the division assisting line extends across all sides of unit lattices through which the division assisting line extends, of all unit lattices of the crystalline structure, and is tangential to the contour of the chip to be fabricated from the substrate, on the upper surface of the substrate.

2. The method of manufacturing an optionally shaped chip according to claim 1, wherein the division assisting line extends perpendicularly across those sides extending in one direction of the unit lattices that make up the crystalline structure of the substrate, on the upper surface of the substrate.

3. The method of manufacturing an optionally shaped chip according to claim 1, wherein the substrate is a substrate made of silicon carbide.
